(19) United States
(12) Patent Application Publication
(10) Pub. No.: US 2009/0159720 A1
(43) Pub. Date: Jun. 25, 2009

(54) Sandwich Piezoelectric Ceramic Ultrasonic Atomizer

(75) Inventors: XIANGHUA FANG, Suzhou (CN); TIEZHENG PAN, Suzhou (CN)

Correspondence Address: GLOBAL IP SERVICES, 7285 W. Eagle Court, Winton, CA, 95388, US

(73) Assignee: KUNSHAN PANT PIEZOELECTRIC TECH CO., LTD., Suzhou (CN)

(21) Appl. No.: 12/111,187

(22) Filed: Apr. 28, 2008

(30) Foreign Application Priority Data
Dec. 25, 2007 (CN) 200720129603.7

(51) Int. Cl. B05B 3/04; H01L 41/083; H01L 41/187

(52) U.S. Cl. 239/102.2; 310/328; 310/358

(57) ABSTRACT

A sandwich piezoelectric ceramic ultrasonic atomizer has two piezoelectric ceramic plates (1) and one metal sheet (2). The metal sheet is securely clamped between the two piezoelectric ceramic plates. The two piezoelectric ceramic plates are respectively formed with a through-hole overlapping and communicated with each other, and the metal sheet completely covers the two through-holes. The present invention improves the reliability of adhesion between the metal sheet and the piezoelectric ceramic plates, thus increasing the energy conversion efficiency and extending the service life. When a bending vibration mode is adopted, the sheet metal diaphragm may be used, thereby simplifying the structure and reducing the processing cost.

### CROSS REFERENCE TO RELATED PATENT APPLICATION

This application claims the priority of the Chinese patent application No. 200720129603.7 filed on Dec. 25, 2007, which is incorporated herein by reference.

### BACKGROUND OF THE INVENTION

1. Field of Invention

The present invention relates to a piezoelectric ceramic atomizer for liquid atomization, in particularly, to a piezoelectric ultrasonic atomizer adapted for liquid atomization driven by low voltage and low power, for example, applicable to home fragrance diffusers, automobile humidifiers, portable liquid medicament atomizers, and so on.

2. Related Art

Vibration of a piezoelectric ultrasonic atomizer is a common technique for atomizing liquid.

However, prior to the present invention, in a conventional piezoelectric ultrasonic atomizer, a metal diaphragm is attached on the surface of a piezoelectric ceramic plate, and is driven by the planar vibration mode of the piezoelectric ceramic plate to vibrate, so as to atomize liquid. The attachment of the metal diaphragm of the atomizer of such structure is unstably, so the energy conversion efficiency is low, and the metal diaphragm in use may easily come off, thus reducing the service life.

The current atomizer adopts a radial drive mode of the piezoelectric ceramic plate. The metal sheet used for the drive mode must be cap-shaped, so as to convert the radial vibration mode of the piezoelectric ceramic plate into an axial vibration mode so as to achieve atomization. Due to the low energy conversion efficiency, micro-pores in the metal diaphragm must be controlled within a small range, which results in a higher processing difficulty, and the micro-pores may be easily clogged in use.

### SUMMARY OF THE INVENTION

Accordingly, in order to solve the above deficiencies, the present invention is directed to a sandwich piezoelectric ceramic ultrasonic atomizer. The metal sheet is firmly joined with the piezoelectric ceramic plates, thus achieving higher energy conversion efficiency and a longer service life. Meanwhile, the structure of the metal diaphragm can be simplified, the diameter of the atomizer orifices is larger and the metal diaphragm may be planar-shaped, which is easy to process.

In order to solve the above technical problem, the present invention is directed to provide a sandwich piezoelectric ceramic ultrasonic atomizer, which includes two piezoelectric ceramic plates and a metal sheet. The metal sheet is securely clamped between the two piezoelectric ceramic plates, the two piezoelectric ceramic plates are respectively formed with a through-hole overlapping and communicated with each other. The metal sheet completely covers the two through-holes (the through-holes may be in various shapes according to actual requirements).

The present invention further provides the following technical scheme.

The two piezoelectric ceramic plates are connected in series with facing surfaces of a same polarity (both positive or both negative), so as to achieve bending vibration.

The two piezoelectric ceramic plates are connected in series with facing surfaces of opposite polarities (one positive and the other negative), so as to achieve radial extension vibration.

The two piezoelectric ceramic plates are connected in parallel. An edge of the metal sheet extends from a periphery of the two piezoelectric ceramic plates (or a pad is disposed on periphery of the two piezoelectric ceramic plates, and connects the metal sheet). The facing surfaces of the two piezoelectric ceramic plates have opposite polarities (one positive and the other negative), so as to achieve bending vibration.

The two piezoelectric ceramic plates are connected in parallel. The edge of the metal sheet extends from the periphery of the two piezoelectric ceramic plates (or a pad is disposed on periphery of the two piezoelectric ceramic plates, and connects the metal sheet). The facing surfaces of the two piezoelectric ceramic plates have the same polarity (both positive or both negative), so as to achieve radial extension vibration.

In a bending vibration mode, parts of the metal sheet in the through-holes are formed with atomizer orifices and are flat plate-shaped, which is easy to process and costs less.

In the radial vibration mode, parts of the metal sheet in the through-holes are formed with atomizer orifices and are dome-shaped (necessarily cap-shaped).

An outer diameter of the metal sheet is greater than, equal to, or smaller than that of the piezoelectric ceramic plates.

In the radial vibration mode, a vibration frequency of the piezoelectric ceramic plates is in a range of 160 Hz to 260 Hz.

In the bending vibration mode, the vibration frequency of the piezoelectric ceramic plates is in a range of 80 Hz to 200 Hz.

The present invention has the following beneficial effects. Though the clamping structure, the metal sheet and the piezoelectric ceramic plates may be firmly joined, and the metal sheet may not be easily come off, thus achieving a longer service life. Further, the bending vibration mode may be adopted. In the bending vibration mode, the structure of the metal sheet can be simplified, and a planar metal sheet can be used, which is easy to process. In view of the above, according to the present invention, the metal sheet is firmly joined with the piezoelectric ceramic plates, thus achieving higher energy conversion efficiency and a longer service life. Meanwhile, the structure of the metal sheet can be simplified, the diameter of the atomizer orifices is larger, and the metal sheet may be planar-shaped (the metal sheet is planar-shaped in the bending vibration mode), which is easy to process.

### BRIEF DESCRIPTION OF THE DRAWINGS

The present invention will become more fully understood from the detailed description given herein below for illustration only, and thus are not limitative of the present invention, and wherein:

FIG. 1 is a plan view of a structure of the present invention;

FIG. 2 is a sectional view of a cap-shaped metal sheet with atomizer orifices according to the present invention;

FIG. 3 is a sectional view of a cap-shaped metal sheet without atomizer orifices according to the present invention;

FIG. 4 is a sectional view of a planar-shaped metal sheet a according to the present invention;

FIG. 5 is a sectional view of a metal sheet larger than piezoelectric ceramic plates according to the present invention;

FIG. 6 is a plan view of a metal sheet with a pad according to the present invention;

FIG. 7 is a schematic view illustrating bending vibration of the present invention when connected in series;

FIG. 8 is a schematic view illustrating bending vibration of the present invention when connected in parallel;

FIG. 9 is a schematic view illustrating radial extension vibration of the present invention when connected in parallel; and

FIG. 10 is a schematic view illustrating radial extension vibration of the present invention when connected in series.

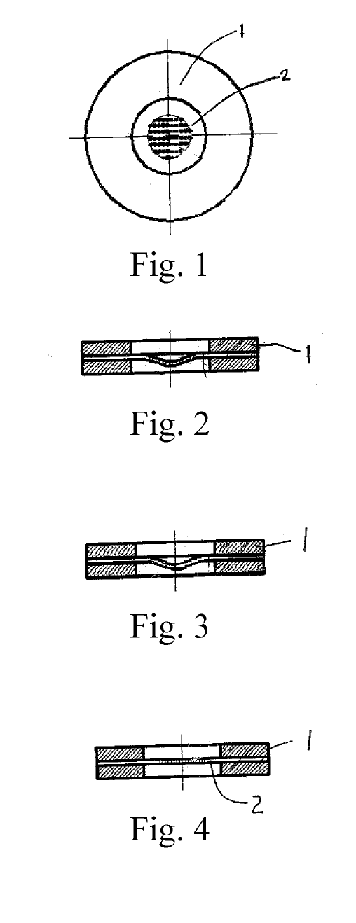

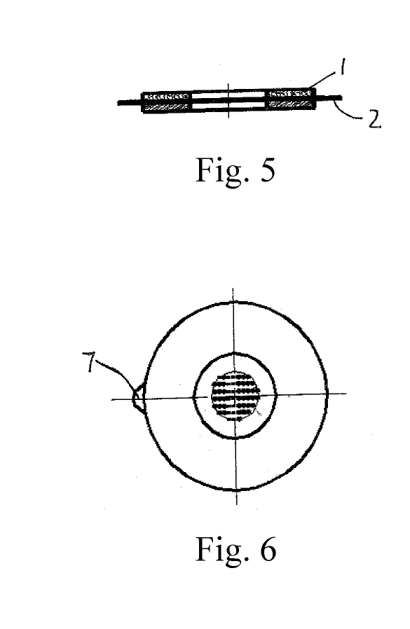

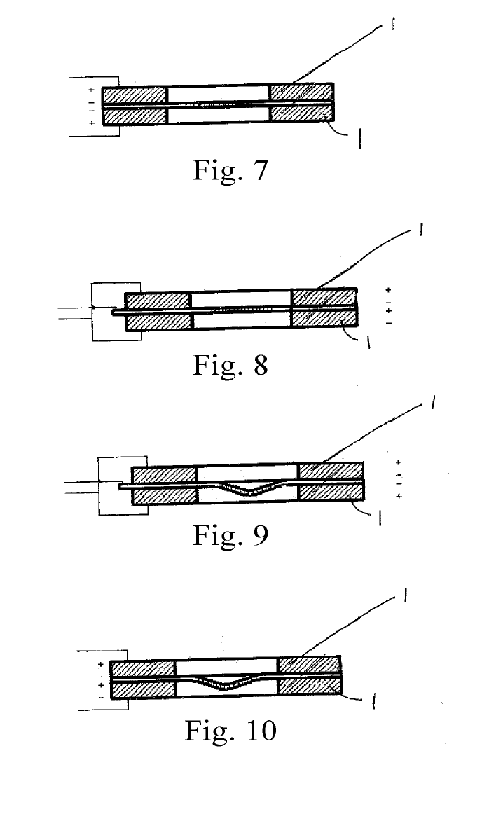

### DETAILED DESCRIPTION OF THE INVENTION

### Embodiment

A sandwich piezoelectric ceramic ultrasonic atomizer includes two piezoelectric ceramic plates 1 and one metal sheet 2. The metal sheet is securely clamped between the two piezoelectric ceramic plates. The two piezoelectric ceramic plates are respectively formed with a through-hole overlapping and communicated with each other. The metal sheet completely covers the two through-holes (the through-holes may be in various shapes according to actual requirements).

The two piezoelectric ceramic plates are connected in series with facing surfaces of the same polarity (both positive or both negative), so as to achieve bending vibration.

The two piezoelectric ceramic plates are connected in series with facing surfaces of opposite polarities (one positive and the other negative), so as to achieve radial extension vibration.

The two piezoelectric ceramic plates are connected in parallel. The edge of the metal sheet extends from the periphery of the two piezoelectric ceramic plates (or a pad is disposed on the periphery of the two piezoelectric ceramic plates, and connects the metal sheet). The facing surfaces of the two piezoelectric ceramic plates have opposite polarities (one positive and the other negative), so as to achieve bending vibration.

The two piezoelectric ceramic plates are connected in parallel. The edge of the metal sheet extends from the periphery of the two piezoelectric ceramic plates (or a pad 7 is disposed on the periphery of the two piezoelectric ceramic plates, and connects the metal sheet). The facing surfaces of the two piezoelectric ceramic plates have the same polarity (both positive or negative), so as to achieve radial extension vibration.

In the bending vibration mode, parts of the metal sheet in the through-holes are formed with atomizer orifices and are flat plate-shaped, which is easy to process and costs less.

In the radial vibration mode, parts of the metal sheet in the through-holes are formed with atomizer orifices and are dome-shaped (necessarily cap-shaped).

The outer diameter of the metal sheet is greater than, equal to, or smaller than that of the piezoelectric ceramic plates.

In the radial vibration mode, the vibration frequency of the piezoelectric ceramic plates is in a range of 160 Hz to 260 Hz.

In the bending vibration mode, the vibration frequency of the piezoelectric ceramic plates is in a range of 80 Hz to 200 Hz.

In this embodiment, the parallel connection of the two piezoelectric ceramic plates may reduce the input voltage (which can be achieved in either of the bending vibration and the radial vibration modes), thus saving power.

In the bending vibration mode of this embodiment, the metal sheet is planar-shaped, which is easy to process and greatly reduces the processing cost.

What is claimed is:

1. A sandwich piezoelectric ceramic ultrasonic atomizer comprising two piezoelectric ceramic plates and a metal sheet, the metal sheet is clamped between the two piezoelectric ceramic plates, each piezoelectric ceramic plate has a through-hole, two through-holes are overlapped and separated completely by the metal sheet.

2. The sandwich piezoelectric ceramic ultrasonic atomizer according to claim 1, wherein the two piezoelectric ceramic plates are connected in series with facing surfaces of a same polarity, so as to achieve bending vibration.

3. The sandwich piezoelectric ceramic ultrasonic atomizer according to claim 1, wherein the two piezoelectric ceramic plates are connected in series with facing surfaces of opposite polarities, so as to achieve radial extension vibration.

4. The sandwich piezoelectric ceramic ultrasonic atomizer according to claim 1, wherein the two piezoelectric ceramic plates are connected in parallel, an edge of the metal sheet extends to outside of the periphery of the two piezoelectric ceramic plates, and the facing surfaces of the two piezoelectric ceramic plates have opposite polarities so as to achieve bending vibration.

5. The sandwich piezoelectric ceramic ultrasonic atomizer according to claim 1, wherein the two piezoelectric ceramic plates are connected in parallel, an edge of the metal sheet extends to outside of the periphery of the two piezoelectric ceramic plates, and the facing surfaces of the two piezoelectric ceramic plates have the same polarity so as to achieve radial extension vibration.

6. The sandwich piezoelectric ceramic ultrasonic atomizer according to claim 2, wherein the area of the metal sheet defined by the through-holes is flat and has atomizer orifices.

7. The sandwich piezoelectric ceramic ultrasonic atomizer according to claim 4, wherein the area of the metal sheet defined by the through-holes is flat and has atomizer orifices.

8. The sandwich piezoelectric ceramic ultrasonic atomizer according to claim 3, wherein the area of the metal sheet defined by the through-holes is dome and has atomizer orifices.

9. The sandwich piezoelectric ceramic ultrasonic atomizer according to claim 5, wherein the area of the metal sheet defined by the through-holes is dome and has atomizer orifices.

10. The sandwich piezoelectric ceramic ultrasonic atomizer according to claim 1, wherein a pad is disposed on the periphery of the two piezoelectric ceramic plates, and connects with the metal sheet.

11. The sandwich piezoelectric ceramic ultrasonic atomizer according to claim 3, wherein in the radial vibration mode, the vibration frequency of the piezoelectric ceramic plates is in a range of 160 Hz to 260 Hz.

12. The sandwich piezoelectric ceramic ultrasonic atomizer according to claim 5, wherein in the radial vibration mode, the vibration frequency of the piezoelectric ceramic plates is in a range of 160 Hz to 260 Hz.

13. The sandwich piezoelectric ceramic ultrasonic atomizer according to claim 2, wherein in the bending vibration mode, the vibration frequency of the piezoelectric ceramic plates is in a range of 80 Hz to 200 Hz.

14. The sandwich piezoelectric ceramic ultrasonic atomizer according to claim 4, wherein in the bending vibration mode, the vibration frequency of the piezoelectric ceramic plates is in a range of 80 Hz to 200 Hz.
